(19) United States
(12) Patent Application Publication
(10) Pub. No.: US 2025/0132694 A1
(43) Pub. Date: Apr. 24, 2025

(54) MULTI-PURPOSE POWER CONVERTER

(71) Applicants: Luis Contreras, Miami, FL (US); Juan Munoz, Miami, FL (US)

(72) Inventors: Luis Contreras, Miami, FL (US); Juan Munoz, Miami, FL (US)

(73) Assignee: AmeTrade, Inc., Miami, FL (US)

(21) Appl. No.: 18/921,187

(22) Filed: Oct. 21, 2024

Related U.S. Application Data
(63) Continuation of application No. PCT/US2024/052062, filed on Oct. 18, 2024.
(60) Provisional application No. 63/692,019, filed on Sep. 6, 2024.
(60) Provisional application No. 63/544,885, filed on Oct. 19, 2023.

(51) Int. Cl. H02M 7/797; H02J 3/38; H02M 1/00; H02M 7/00; H05K 7/14; H05K 7/20

(52) U.S. Cl. CPC H02M 7/797; H02J 3/381; H02M 1/007; H02M 7/003; H05K 7/14325; H05K 7/14329; H05K 7/20927

(57) ABSTRACT

Embodiments of the disclosure relate to a bi-directional power converter. The power converter includes first connectors configured to receive or transmit electrical energy at a first current, a first voltage, and/or a first current form and second connectors configured to receive or transmit electrical energy at a second current, a second voltage, and/or a second current form. The power converter also includes a controller and a plurality of SiC-based transistors in electrical communication with the first connectors and with the second connectors. The controller is configured for switching, using pulse width modulation, the plurality of SiC-based transistors to change the first current, the first voltage, and/or the first current form to the second current, the second voltage, and/or the second current form. The switching is at a frequency up to 50 KHz.

### CROSS-REFERENCE TO RELATED PATENT APPLICATIONS

This patent application is a continuation of International Application No. PCT/US2024/052062, filed on Oct. 18, 2024, which claims the benefit of U.S. Provisional Patent Application No. 63/544,885, filed Oct. 19, 2023, and the benefit of U.S. Provisional Patent Application No. 63/692,019, filed Sep. 6, 2024, the entire teachings and disclosures of which are incorporated herein by reference thereto.

### FIELD OF THE INVENTION

This invention generally relates to power converters and, in particular, to a multi-purpose power converter.

### BACKGROUND OF THE INVENTION

For various practical reasons, power supplies provide power in one particular form, but that form may not be suitable for an intended application. For example, a vehicle, such as a train, ship, or automobile, may include a battery storage for electric operation. Batteries provide DC power, but traction motors of the vehicle may need AC power, in particular multi-phase AC power, to operate. Thus, the power from the batteries must be converted from DC to AC and to a desired voltage and current level. Conversions in high- power applications typically involve high frequency switching, generating significant heat and creating undesirable losses. Accordingly, it would desirable to provide a power converter that is suitable for use in a variety of different applications, that provides a scalable amount of power, and that minimizes power loss associated with switching and heat.

### BRIEF SUMMARY OF THE INVENTION

Embodiments of the present disclosure relate to a multi-purpose power converter that may be utilized for a wide range of applications, including propulsion, solar, wind, energy storage, hydrogen, and electric vehicle charging. As will be discussed more fully below, the multi-purpose power converter provides several improvements in terms of power conversion, size reduction, emissions control, condition monitoring, output filtering, and modularity. Advantageously, multiple power converters can be connected in a variety of different topologies and power ranges to meet the different applications.

Embodiments of the presently disclosed multi-purpose power converter overcome several limitations associated with conventional systems based on the selection, construction, and arrangement of the components within the multi-purpose power converter. In one or more embodiments, the power converter eliminates or minimizes the need for a line filter reactor and charging resistor, resulting in reduced losses, minimal conducted emissions, and a smaller overall size for the complete conversion package. The converter has been developed with the capability of reducing and simplifying a large number of peripheral components traditionally required in a conversion system, which is achievable by reducing losses from high-frequency switching. Additionally, embodiments of the presently disclosed power converter reduce electromagnetic interference and improve electromagnetic compatibility associated with high power energy conversion.

As will be described more fully below, the power converter may be employed as a four-quadrant and bi-directional converter (AC to DC, DC to AC, AC to AC, and DC to DC). In one or more embodiments, the power converter logic maximizes the stabilization by using an internal capacitor bank as an intermediate buffer for the energy.

In one or more embodiments, the power converter addresses issues associated with short power interruptions, providing a stable and uninterrupted power supply. The power converter incorporates the usage of supercapacitors, reducing the need for resistors through energy storage (peak shaving), which also allows for small periods of operation without external power. In this way, the power converter provides enhanced operational flexibility.

In one or more embodiments, the power converter is operational with advanced edge computing technology to provide condition monitoring. Specifically, embodiments of the power converter provide real-time monitoring and analysis of peripheral components, such as motors, gearboxes, power cables, and power inputs, amongst other possibilities. Additionally, embodiments of the power converter system provide event datalogging capacity, facilitating advanced diagnostics. In certain embodiments, the datalogging capacity can store a large amount of data.

In one or more embodiments, an integrated output filter of the power converter limits the rate of change of voltage (dv/dt) and allows for operation of regular peripheral components, extending equipment life based on the reduced dv/dt and providing a cleaner sine wave output.

In one or more embodiments, the power converter system is modular and expandable, offering for example options for 750 V, 1500 V, and 3000 V systems. Further, the power converters are parallelizable from 100 kW up to 6 MW (8000 HP) inverters, providing customizable output for various power requirements.

In a first aspect, embodiments of the disclosure relate to a bi-directional power converter. The bi-directional power converter comprises a housing comprising a first side surface, a second side surface, and a plurality of peripheral surfaces. The second side surface is opposite to and spatially disposed from the first side surface, and the plurality of peripheral surfaces connecting the first side surface to the second side surface around a periphery of the housing. A first set of electrical connectors is disposed on a first peripheral surface of the plurality of peripheral surfaces. A second set of electrical connectors disposed on the first peripheral surface. The first set of electrical connectors are arranged in a first line, and the second set of electrical connectors are arranged in a second line. The first line and the second line are each substantially parallel to an edge of the housing formed by an intersection of the first side surface and the first peripheral surface. The first set of connectors are configured to transmit or receive electrical energy at at least one of a first current, a first voltage, or a first current form, and the second set of connectors are configured to receive or transmit electrical energy at at least one of a second current, a second voltage, or a second current form that is different from the at least one of the first current, the first voltage, or the first current form.

In a second aspect, embodiments of the disclosure relate to the bi-directional power converter of the first aspect in which the first line and the second line are offset from each other between the first side surface and the second side surface.

In a third aspect, embodiments of the disclosure relate to the bi-directional power converter of the first aspect in which the first line and the second line define a single continuous line.

In a fourth aspect, embodiments of the disclosure relate to the bi-directional power converter of any of the first aspect to the third aspect in which the first set of electrical connectors and the second set of electrical connectors are screw connectors.

In a fifth aspect, embodiments of the disclosure relate to the bi-directional power converter of any of the first aspect to the third aspect the first set of electrical connectors and the second set of electrical connectors are blade connectors.

In a sixth aspect, embodiments of the disclosure relate to the bi-directional power converter of any of the first aspect to the fifth aspect in which the first set of connectors comprises a first connector and a second connector. The first connector is connected to a first bus, and the second connector is connected to a second bus. The bi-directional power converter further comprises a plurality of inverter circuits connected between the first bus and the second bus, and each connector of the second set of connectors is connected to the second bus such that an inverter circuit of the plurality of inverter circuits and a connector of the second set of connectors is alternatingly connected to the second bus.

In a seventh aspect, embodiments of the disclosure relate to the bi-directional power converter of the sixth aspect in which each inverter circuit of the plurality of inverter circuits comprises two transistors.

In an eighth aspect, embodiments of the disclosure relate to the bi-directional power converter of the seventh aspect in which each transistor is an Si IGBT.

In a ninth aspect, embodiments of the disclosure relate to the bi-directional power converter of the seventh aspect in which each transistor is an SiC-based transistor.

In a tenth aspect, embodiments of the disclosure relate to the bi-directional power converter of any of the seventh aspect to the ninth aspect in which the bi-directional power converter further comprises a controller configured to switch each of the transistors of each inverter circuit of the plurality of inverter circuits.

In an eleventh aspect, embodiments of the disclosure relate to the bi-directional power converter of the tenth aspect in which the controller is configured to switch each of the transistors a frequency up to 50 kHz.

In a twelfth aspect, embodiments of the disclosure relate to the bi-directional power converter of any of the first aspect to the eleventh aspect in which a thickness of the bi-directional power converter defined as a distance between the first side surface and the second side surface is in a range from 100 mm to 500 mm.

In a thirteenth aspect, embodiments of the disclosure relate to the bi-directional power converter of any the twelfth aspect in which the first side surface and the second side surface each comprise a length and a width. The length and the width each are perpendicular to the thickness, and the length is measured parallel to an edge defined by an intersection between the first side surface and the first peripheral surface. The length is 1000 mm or less.

In a fourteenth aspect, embodiments of the disclosure relate to the bi-directional power converter of thirteenth aspect in which the width is 1100 mm or less.

In a fifteenth aspect, embodiments of the disclosure relate to the bi-directional power converter of any of the first aspect to the fourteenth aspect in which the plurality of peripheral surfaces comprises a second peripheral surface opposite to the first peripheral surface and in which the second peripheral surface comprises a heat dissipation feature.

In a sixteenth aspect, embodiments of the disclosure relate to the bi-directional power converter of any of the first aspect to the fourteenth aspect in which the bi-directional power converter further comprises a liquid cooling system disposed on the second peripheral surface. The liquid cooling system comprises a liquid inlet and a liquid outlet configured to provide liquid flow through the liquid cooling system.

In a seventeenth aspect, embodiments of the disclosure relate to the bi-directional power converter of any of the first aspect to the sixteenth aspect in which the bi-directional power converter is configured to provide electrical power in a range from 0.1 MW to 1 MW.

In an eighteenth aspect, embodiments of the disclosure relate to a power supply unit comprising a plurality of the bi-directional power converters according to any of the first aspect to the seventeenth aspect.

In a nineteenth aspect, embodiments of the disclosure relate to the power supply unit of eighteenth aspect in which each bi-directional converter of the plurality of bi-directional power converters is connected to at least one other bi-directional power converter of the plurality of bi-directional power converters using a bus bar.

In a twentieth aspect, embodiments of the disclosure relate to the power supply unit of the eighteenth aspect or the nineteenth aspect in which the plurality of bi-directional power converters are contained in a rack cabinet.

In a twenty-first aspect, embodiments of the present disclosure relate to a bi-directional power converter. The bi-directional power converter comprises a first set of electrical connectors configured to receive or transmit electrical energy at at least one of a first current, a first voltage, or a first current form and a second set of electrical connectors configured to receive or transmit electrical energy at at least one of a second current, a second voltage, or a second current form. The bi-directional power converter further comprises a controller and a plurality of SiC-based transistors in electrical communication with the first set of electrical connectors and with the second set of electrical connectors. The controller is configured for switching, using pulse width modulation, the plurality of SiC-based transistors to change the at least one of the first current, the first voltage, or the first current form to the at least one of the second current, the second voltage, or the second current form. The switching is at a frequency up to 50 kHz.

In a twenty-second aspect, embodiments of the disclosure relate to the bi-directional power converter of the twenty-first aspect in which the first set of connectors comprises a first connector and a second connector. The first connector is connected to a first bus, and the second connector is connected to a second bus. The SiC-based transistors define a plurality of inverter circuits connected between the first bus and the second bus, and each connector of the second set of connectors is connected to the second bus such that an inverter circuit of the plurality of inverter circuits and a connector of the second set of connectors is alternatingly connected to the second bus.

In a twenty-third aspect, embodiments of the disclosure relate to the bi-directional power converter of the twenty-second aspect in which the bi-directional power converter further comprises a capacitor bank connected between the first bus and the second bus such that the capacitor bank is electrically disposed between the first set of connectors and a first inverter circuit of the plurality of inverter circuits.

In a twenty-fourth aspect, embodiments of the disclosure relate to the bi-directional power converter of any of the twenty-first aspect to the twenty-third aspect in which the bi-directional power converter further comprises a plurality of current sensors configured to sense current flowing between each of the plurality of SiC-based transistors and the second set of electrical connectors. The controller monitors a status of the bi-directional power converter based at least in part on feedback from the plurality of current sensors.

In a twenty-fifth aspect, embodiments of the disclosure relate to the bi-directional power converter of any of the twenty-first aspect to the twenty-fourth in which the bi-directional power converter further comprises a housing comprising a first side surface, a second side surface, and a plurality of peripheral surfaces. The second side surface is opposite to and spatially disposed from the first side surface, and the plurality of peripheral surfaces connect the first side surface to the second side surface around a periphery of the housing. The plurality of peripheral surfaces comprises a first peripheral surface and a second peripheral surface, and the second peripheral surface is opposite to the first peripheral surface. The first second of electrical connectors and the second set of electrical connectors are disposed on the first peripheral surface.

In a twenty-sixth aspect, embodiments of the disclosure relate to the bi-directional power converter of the twenty-fifth aspect in which the first set of electrical connectors are arranged in a first line and in which the second set of electrical connectors are arranged in a second line. The first line and the second line are each substantially parallel to an edge of the housing formed by an intersection of the first side surface and the first peripheral surface.

In a twenty-seventh aspect, embodiments of the disclosure relate to the bi-directional power converter of the twenty-fifth aspect or the twenty-sixth aspect in which the plurality of SiC-based transistors are mounted to an interior of the second peripheral surface.

In a twenty-eighth aspect, embodiments of the disclosure relate to the bi-directional power converter of the twenty-seventh aspect in which the second peripheral surface is liquid cooled.

In a twenty-ninth aspect, embodiments of the disclosure relate to the bi-directional power converter of the twenty-seventh aspect in which the second peripheral surface comprises a heat dissipation feature.

In a thirtieth aspect, embodiments of the disclosure relate to the bi-directional power converter of any of the twenty-first aspect to the twenty-ninth aspect in which the controller is configured to operate independently to control the bi-directional power converter without another controller external to the bi-directional power converter.

In a thirty-first aspect, embodiments of the disclosure relate to the bi-directional power converter of any of the twenty-first aspect to the thirtieth aspect in which the controller is configured to communicate and coordinate power conversion operations with one or more other controllers of one or more other bi-directional power converters.

In a thirty-second aspect, embodiments of the disclosure relate to the bi-directional power converter of any of the twenty-first aspect to the thirty-first aspect in which the controller is configured to communicate wirelessly over a network to a central server for asset monitoring.

In a thirty-third aspect, embodiments of the disclosure relate to the bi-directional power converter of any of the twenty-first aspect to the thirty-second aspect in which the first set of electrical connectors and the second set of electrical connectors are configurable between a plurality of topologies for changing the at least one of the first current, the first voltage, or the first current form to the at least one of the second current, the second voltage, or the second current form.

In a thirty-fourth aspect, embodiments of the disclosure relate to a power supply unit comprising a plurality of the bi-directional power converters according to any of the twenty-first aspect to the thirty-third aspect.

In a thirty-fifth aspect, embodiments of the disclosure relate to the power supply unit of the thirty-fourth aspect in which the first set of electrical connectors of each bi-directional power converter comprises a first connector and a second connector. The first connector of the first set of electrical connectors of each of the plurality of bi-directional power converters is electrically connected, and the second connector of the first set of electrical connectors of each of the plurality of bi-directional power converters is electrically connected. The first connectors and the second connectors are configured for DC power input/output.

In a thirty-sixth aspect, embodiments of the disclosure relate to the power supply unit of the thirty-fifth aspect in which the second set of electrical connectors of each bi-directional power converter comprises a first connector, a second connector, and a third connector. The first connector of the second set of electrical connectors of each of the plurality of bi-directional power converters is electrically connected. The second connector of the second set of electrical connectors of each of the plurality of bi-directional power converters is electrically connected, and the third connector of the second set of electrical connectors of each of the plurality of the bi-directional power converters is electrically connected. The first connectors, the second connectors, and the third connectors are configured for 3-phase AC power input/output.

In a thirty-seventh aspect, embodiments of the disclosure relate to the power supply unit of the thirty-fifth aspect in which the second set of electrical connectors of each bi-directional power converter comprises a first connector, a second connector, and a third connector. The plurality of the bi-directional power converters comprises a first bi-directional power converter, a second bi-directional power converter, and a third bi-directional power converter. The first connector, the second connector, and the third connector of the second set of connectors of the first bi-directional power converter are electrically connected. The first connector, the second connector, and the third connector of the second set of connectors of the second bi-directional power converter are electrically connected, and the first connector, the second connector, and the third connector of the second set of connectors of the third bi-directional power converter are electrically connected. The second set of electrical connectors of the first bi-directional power converter is configured to output a first phase of 3-phase AC power. The second set of electrical connectors of the second bi-directional power converter is configured to output a second phase of 3-phase AC power, and the second set of electrical connectors of the third bi-directional power converter is configured to output a third phase of 3-phase AC power.

In a thirty-eighth aspect, embodiments of the disclosure relate to the power supply unit of the thirty-fifth aspect in which the plurality of the bi-directional power converters comprises a first bi-directional power converter and a second bi-directional power converter. The second set of electrical connectors of the first bi-directional power converters are electrically connected, and the second set of electrical connectors of the second bi-directional power converters are electrically connected. The second set of electrical connectors of the first bi-directional power converter and the second set of connectors of the second bi-directional power converter are configured to provide a further DC power input/output at a different voltage or current that the DC power input/output of the first set of electrical connectors.

In a thirty-ninth aspect, embodiments of the disclosure relate to the power supply unit of the thirty-fourth aspect in which the second set of electrical connectors of each bi-directional power converter comprises a first connector, a second connector, a third connector, and a fourth connector. Each first connector of the plurality of bi-directional power converters is electrically connected. Each second connector of the plurality of bi-directional power converters is electrically connected. Each third connector of the plurality of bi-directional power converters is electrically connected, and each fourth connector of the plurality of bi-directional power converters is electrically connected. The first connectors and the second connectors of the plurality of bi-directional power converters are configured for a first DC power input/output, and the third connectors and the fourth connectors of the plurality of bi-directional power converters are configured for a second DC power input/output that is different from the first DC power input/output in one of current, voltage, or pulse width or frequency.

In a fortieth aspect, embodiments of the present disclosure relate to a power storage container. The power storage container comprises the bi-directional power converter according to any of first aspect to the seventeenth aspect or the twenty-first aspect to the thirty-third aspect or the power supply unit according to any of the eighteenth aspect to the eighteenth aspect to the twentieth aspect or the thirty-fourth aspect to the thirty-ninth aspect. The power storage container further comprises an energy storage device in electrical communication with the bi-directional power converter or the power supply unit. The energy storage device is configured to output electrical power at at least one of a first current, a first voltage, or a first current form to the bi-directional power converter or the power supply unit. The bi-directional power converter or the power supply unit is configured to output electrical power at at least one of a second current, a second voltage, or a second current form that is different from at least one of the first current, the first voltage, or the first current form.

In a forty-first aspect, embodiments of the present disclosure relate to the power storage container of the fortieth aspect in which the energy storage device comprises a battery bank.

In a forty-second aspect, embodiments of the present disclosure relate to the power storage container of the fortieth aspect in which the energy storage device comprises a hydrogen electrolyzer.

In a forty-third aspect, embodiments of the present disclosure relate to the power storage container of any of the fortieth aspect to the forty-second aspect in which the container is an intermodal shipping container according to ISO 668:2020.

In a forty-fourth aspect, embodiments of the present disclosure relate to the power storage container of any of the fortieth aspect to the forty-third aspect in which the power storage container further comprises a filtering module configured to filter the electrical power output of the bi-directional power converter or the power supply unit.

In a forty-fifth aspect, embodiments of the present disclosure relate to a method of operating a bi-directional power converter. In the method, electrical energy is provided at at least one of a first current, a first voltage, or a first current form to a first set of electrical connectors. A plurality of transistors in electrical communication with the first set of electrical connectors are switched to change the at least one of the first current, the first voltage, or the first current form to at least one of a second current, a second voltage, or a second current form. The electrical energy is transmitted at the at least one of the second current, the second voltage, or the second current form to a second set of electrical connectors. A controller controls the switching of the plurality of transistors using pulse with modulation and at a frequency of up to 50 KHz.

In a forty-sixth aspect, embodiments of the present disclosure relate to the method of the forty-fifth aspect in which the first set of connectors comprises a first connector and a second connector. The first connector is connected to a first bus, and the second connector is connected to a second bus. The plurality of transistors define a plurality of inverter circuits connected between the first bus and the second bus. Each connector of the second set of connectors is connected to the second bus such that an inverter circuit of the plurality of inverter circuits and a connector of the second set of connectors is alternatingly connected to the second bus.

In a forty-seventh aspect, embodiments of the present disclosure relate to the method of the forty-sixth aspect in which a capacitor bank is connected between the first bus and the second bus such that the capacitor bank is electrically disposed between the first set of connectors and a first inverter circuit of the plurality of inverter circuits.

In a forty-eighth aspect, embodiments of the present disclosure relate to the method of any of the forty-fifth aspect to the forty-seventh aspect in which the method further comprises sensing current flowing between each of the plurality of transistors and the second set of electrical connectors using a plurality of current sensors. Using the controller, a status of the bi-directional power converter is monitored based at least in part on feedback from the plurality of current sensors.

In a forty-ninth aspect, embodiments of the present disclosure relate to the method of any of the forty-fifth aspect to the forty-eighth aspect in which the bi-directional power converter comprises a housing comprising a first side surface, a second side surface, and a plurality of peripheral surfaces. The second side surface is opposite to and spatially disposed from the first side surface, and the plurality of peripheral surfaces connect the first side surface to the second side surface around a periphery of the housing. The plurality of peripheral surfaces comprises a first peripheral surface and a second peripheral surface, and the second peripheral surface is opposite to the first peripheral surface. The first set of electrical connectors and the second set of electrical connectors are disposed on the first peripheral surface.

In a fiftieth aspect, embodiments of the present disclosure relate to the method of the forty-ninth aspect in which the first set of electrical connectors are arranged in a first line, in which the second set of electrical connectors are arranged in a second line, and in which the first line and the second line are each substantially parallel to an edge of the housing formed by an intersection of the first side surface and the first peripheral surface.

In a fifty-first aspect, embodiments of the present disclosure relate to the method of the forty-ninth aspect or the fiftieth aspect in which the plurality of transistors are mounted to an interior of the second peripheral surface.

In a fifty-second aspect, embodiments of the present disclosure relate to the method of the fifty-first aspect in which the method further comprises liquid cooling the second peripheral surface.

In a fifty-second aspect, embodiments of the present disclosure relate to the method of the fifty-first aspect in which the method further comprises dissipating heat from the second peripheral surface using heatsink fins.

In a fifty-fourth aspect, embodiments of the present disclosure relate to the method of any of the forty-fifth aspect to the fifty-third aspect in which the method further comprises operating the controller to control the bi-directional power converter independently of another controller external to the bi-directional power converter.

In a fifty-fifth aspect, embodiments of the present disclosure relate to the method of any of the forty-fifth aspect to the fifty-fourth aspect in which the method further comprises communicating, using the controller, with one or more other controllers of one or more other bi-directional power converters to coordinate a power conversion operation.

In a fifty-sixth aspect, embodiments of the present disclosure relate to the method of any of the forty-fifth aspect to the fifty-fifth aspect in which the method further comprises wirelessly communicating, using the controller, over a network to a central server for asset monitoring.

In a fifty-seventh aspect, embodiments of the present disclosure relate to the method of any of the forty-fifth aspect to the fifty-sixth aspect in which the method further comprises configuring the first set of electrical connectors and the second set of electrical connectors between a plurality of topologies for changing the at least one of the first current, the first voltage, or the first current form to the at least one of the second current, the second voltage, or the second current form.

In a fifty-eighth aspect, embodiments of the present disclosure relate to the method of any of the forty-fifth aspect to the fifty-seventh aspect in which the method further comprises connecting the bi-directional power converter to one or more other bi-directional power converters to create a power supply unit.

In a fifty-ninth aspect, embodiments of the present disclosure relate to the method of the fifty-eighth aspect in which the first set of electrical connectors of each bi-directional power converter comprises a first connector and a second connector. In the method, the first connectors of the first sets of electrical connectors of the bi-directional power converters are electrically connected to each other. The second connectors of the first sets of electrical connectors of the bi-directional power converters are electrically connected to each other. The first connectors and the second connectors of the first sets of electrical connectors are connected to DC power.

In a sixtieth aspect, embodiments of the present disclosure relate to the method of the fifty-ninth aspect in which the second set of electrical connectors of each bi-directional power converter comprises a first connector, a second connector, and a third connector. In the method, the first connectors of the second sets of electrical connectors of the bi-directional power converters are electrically connected to each other. The second connectors of the second sets of electrical connectors of the bi-directional power converters are electrically connected to each other. The third connectors of the second sets of electrical connectors of the bi-directional power converters are electrically connected to each other. The first connectors, the second connectors, and the third connectors are connected to 3-phase AC power.

In a sixty-first aspect, embodiments of the present disclosure relate to the method according to the sixtieth aspect in which the method further comprises inputting the DC power at the first sets of the electrical connectors and outputting the 3-phase AC power at the second sets of electrical connectors.

In a sixty-second aspect, embodiments of the present disclosure relate to the method according to the sixtieth aspect in which the method further comprises inputting the 3-phase AC power at the second sets of the electrical connectors and outputting the DC power at the first sets of the electrical connectors.

In a sixty-third aspect, embodiments of the disclosure relate to the method of the fifty-ninth aspect in which the second set of electrical connectors of each bi-directional power converter comprises a first connector, a second connector, and a third connector. The bi-directional power converters comprise a first bi-directional power converter, a second bi-directional power converter, and a third bi-directional power converter. In the method, the first connector, the second connector, and the third connector of the second set of connectors of the first bi-directional power converter are electrically connected to each other. The first connector, the second connector, and the third connector of the second set of connectors of the second bi-directional power converter are electrically connected to each other. The first connector, the second connector, and the third connector of the second set of connectors of the third bi-directional power converter are electrically connected to each other. Further, in the method, a first phase of 3-phase AC power is output using the second set of electrical connectors of the first bi-directional power converter. A second phase of 3-phase AC power is output using the second set of electrical connectors of the second bi-directional power converter, and a third phase of 3-phase AC power is output using the second set of electrical connectors of the third bi-directional power converter.

In a sixty-fourth aspect, embodiments of the present disclosure relate to the method of the fifty-ninth aspect in which the bi-directional power converters comprise a first bi-directional power converter and a second bi-directional power converter. In the method, the first set of electrical connectors of the first bi-directional power converters are electrically connected to each other. The second set of electrical connectors of the second bi-directional power converters are electrically connected to each other. A first DC power is input using the first set of electrical connectors of the first bi-directional power converter and the second bi-directional power converter. A second DC power is output using the second set of electrical connectors of the first bi-directional power converter and the second bi-directional power converter. The second DC power is at a different voltage or current that the first DC power.

In a sixty-fifth aspect, embodiments of the present disclosure relate to the method according to the fifty-eighth aspect in which the second set of electrical connectors of each bi-directional power converter comprises a first connector, a second connector, a third connector, and a fourth connector. In the method, the first connectors of the second sets of electrical connectors of the bi-directional power converters are electrically connected to each other. The second connector of the second sets of electrical connectors of the bi-directional power converters are electrically connected to each other. The third connectors of the second sets of electrical connectors of the bi-directional power converters are electrically connected to each other. The fourth connectors of the second sets of electrical connectors of the bi-directional power converters are electrically connected to each other. A first DC power is input using the first connectors and the second connectors of the second sets of electrical connectors of the bi-directional power converters. A second DC power is output using the third connectors and the fourth connectors of the second sets of electrical connectors of the bi-directional power converters. The second DC power is different from the first DC power in at least one of current, voltage, or pulse width or frequency.

According to the present disclosure, various other aspects are provided, such as (i) a power converter with included, configurable and flexible logic to be able to operate in multiple topologies either using a single unit or multiple units; (ii) a power converter integrated with all measuring current, voltages, speed sensor inputs and digital Input/Outputs that allows to operate independently without the need of external controller; (iii) a power converter with a mechanical design to operate rack mounted or stand alone; (iv) a power converter capable of operating with the same external mechanical design with different DC Link voltages up to 3 kV; (v) a power converter capable of operating with the same external mechanical design with liquid, forced air and natural convection cooling with modifications only to the heat exchanger area; (vi) a power converter capable of operating with the same external mechanical design using Silicon Based (Si) IGBTs and/or Silicon Carbide (SiC) FETs; (vii) a power converter capable of paralleling outputs in AC; and (viii) a power converter capable of limiting automatically the output power based on internal diagnostics to minimize catastrophic failures due to overload or overtemperature.

Other aspects, objectives and advantages of the invention will become more apparent from the following detailed description when taken in conjunction with the accompanying drawings.

### BRIEF DESCRIPTION OF THE DRAWINGS

The accompanying drawings incorporated in and forming a part of the specification illustrate several aspects of the present invention and, together with the description, serve to explain the principles of the invention. In the drawings:

FIG. 1 depicts a multi-purpose power converter, according to an embodiment of the present disclosure;

FIG. 2 depicts a power supply unit having a plurality of power converters connected together and organized in a rack cabinet, according to an embodiment of the present disclosure;

FIGS. 3A-3B to 7A-7B depict various connection topologies for converting power using one or more power converters, according to exemplary embodiments of the present disclosure;

FIG. 8 is a switching schematic for controlling power inputs and outputs of the power converter, according to an exemplary embodiment;

FIG. 9 schematically depicts an interior of the power converter showing the physical layout of components, according to an exemplary embodiment;

FIG. 10 depicts an example application of the power converter as used as a propulsion converter, according to an exemplary embodiment;

FIG. 11 depicts the system of FIG. 10 further incorporating edge monitoring and control of the system, according to an exemplary embodiment;

FIG. 12 depicts the power converter as used in an energy storage container for regulating charging and discharging of the energy storage container, according to an exemplary embodiment; and

FIGS. 13A-13D depict a power converter as configured for liquid cooling, according to an exemplary embodiment.

While the invention will be described in connection with certain preferred embodiments, there is no intent to limit it to those embodiments. On the contrary, the intent is to cover all alternatives, modifications and equivalents as included within the spirit and scope of the invention as defined by the appended claims.

### DETAILED DESCRIPTION OF THE INVENTION

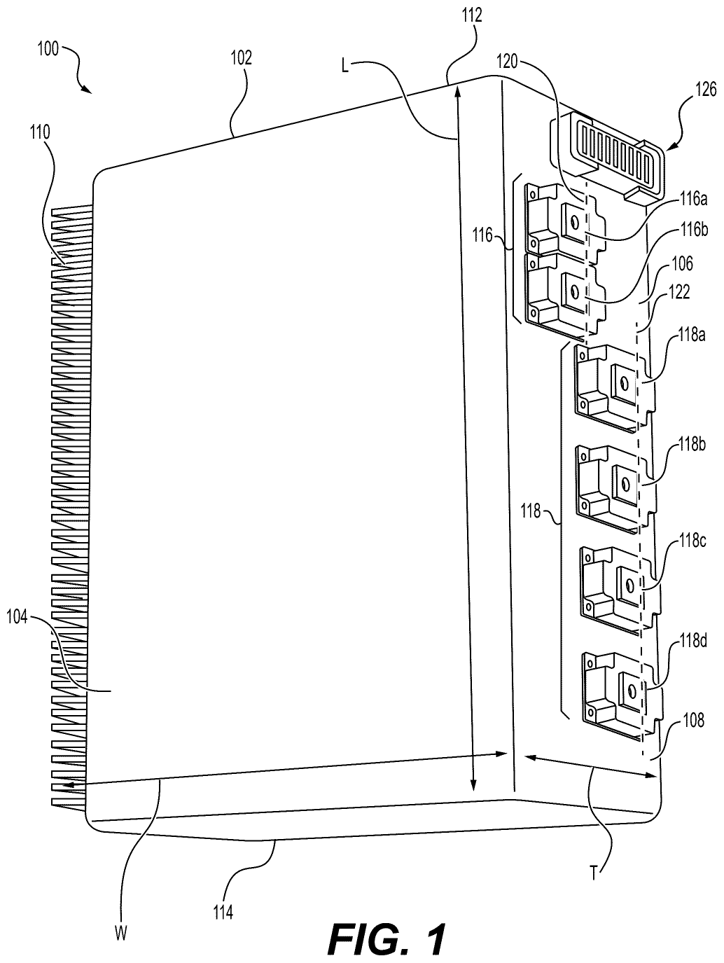

FIG. 1 depicts a power converter 100 according to an embodiment of the present disclosure. The power converter 100 includes a housing 102 having a first side surface 104 and a second side surface 106. The second side surface 106 is opposite to the first side surface 104. The housing 102 further includes a plurality of peripheral surfaces, including a first peripheral surface 108, a second peripheral surface 110, a third peripheral surface 112, and a fourth peripheral surface 114. The second peripheral surface 110 is opposite to the first peripheral surface 108, and the fourth peripheral surface 114 is opposite to the third peripheral surface 112. The peripheral surfaces 108, 110, 112, 114 connect the first side surface 104 to the second side surface 106 and define a substantially rectangular prism shape of the housing 102.

The first side surface 104 and the second side surface 106 define a length L and a width W of the housing 102. In one or more embodiments, the length L of the housing 102 is 1000 mm or less, in particular 700 mm or less, and most particular about 470 mm. In one or more embodiments, the width W of the housing 102 is 1100 mm or less, in particular 1000 mm or less, and most particularly 800 mm or less. The peripheral surfaces 108, 110, 112, 114 define a thickness T of the housing 102 in which the thickness T is perpendicular to the length L and width W. In one or more embodiments, the thickness T is 500 mm or less, in particular 400 mm or less, and most particularly 300 mm or less. In one or more embodiments, the thickness T is in a range from 100 mm to 500 mm. In one or more embodiments, the housing 102 is sized so that the power converter 100 can be fit into a standard rack cabinet, such as for a server.

In one or more embodiments, the first peripheral surface 108 includes a first set of electrical connectors 116, in particular a first connector 116a and a second connector 116b, and a second set of electrical connectors 118, in particular a first connector 118a, a second connector 118b, a third connector 118c, and a fourth connector 118d. In one or more embodiments, the first set of electrical connectors 116 receive electrical energy at a first current, a first voltage, and/or a first current form, and the second set of electrical connectors 118 transmit electrical energy at a second current, a second voltage, and/or a second current form that is different from at least one of the first current, the first voltage, or the first current form. Further, in one or more embodiments, the power converter 100 is bi-directional such that the second set of electrical connectors 118 receive electrical energy at a first current, a first voltage, and/or a first current form, and the first set of electrical connectors 116 transmits electrical energy at a second current, a second voltage, and/or a second current form that is different from at least one of the first current, the first voltage, or the first current form. In still one or more other embodiments, one of the sets of connectors 116, 118 can be used without using the other of the sets of connectors 116, 118. For example, and as will be discussed more fully below, a subset of the second set of electrical connectors 118, such as the first connector 118a and the second connector 118b, act as an input for the power converter 100, and a subset of the second set of electrical connectors 118, such as the third connector 118c and the fourth connector 118d, act as an output for the power converter 100. As will be discussed more fully below, the housing 102 contains electronics and control components that allow for the modification of an electrical power input to a different electrical power output.

In one or more embodiments, the first set of electrical connectors 116 and the second set of electrical connectors 118 are screw connectors, connectable to cables with, e.g., ring, spade, or hook terminals. In one or more embodiments, the first set of electrical connectors 116 and the second set of electrical connectors 118 are blade connectors connectable with a bus bar having clamps that engage the blade connectors.

In one or more embodiments, the first set of electrical connectors 116 is arranged such that all of the connectors 116a, 116b are disposed on a first line 120. In one or more embodiments, the second set of electrical connectors 118 are arranged such that all of the connectors 118a, 118b, 118c, 118d are disposed on a second line 122. In one or more embodiments, the first line 120 is offset from the second line 122. As will be discussed below, the offsetting of the first set of electrical connectors 116 from the second set of electrical connectors 118 relates to the organization of the DC and AC lines within the power converter 100. In one or more embodiments, both the first line 120 and the second line 122 are parallel to an edge of the housing 102 formed by the intersection of the first side surface 104 with the first peripheral surface 108. Advantageously, the arrangement of the sets of electrical connectors 116, 118 on the first peripheral face 108 facilitates the connection of multiple power converters 100 together in a compact and electrically efficient manner using bus bars.

In one or more embodiments, the second peripheral surface 110 includes a heat dissipation feature, such as heatsink fins 124 extending from the second peripheral surface 110. In another embodiment described below, the heat dissipation feature is a liquid cooling system.

In one or more embodiments, the power converter 100 further includes a modular connector port 126 configured to receive a connector cable plug. The modular connector port 126 provides power to the control system within the power converter 100. Additionally, the modular connector port 126 provides communication between the power converter 100 and the system in which it operates. Further, as will be discussed more fully below, the modular connector port 126 allows for connecting and synchronizing of multiple power converters 100 utilized in a power supply unit. An example of a suitable modular connector port 126 is a Han-Modular® available from Harting Technology Group (Espelkamp, Germany).

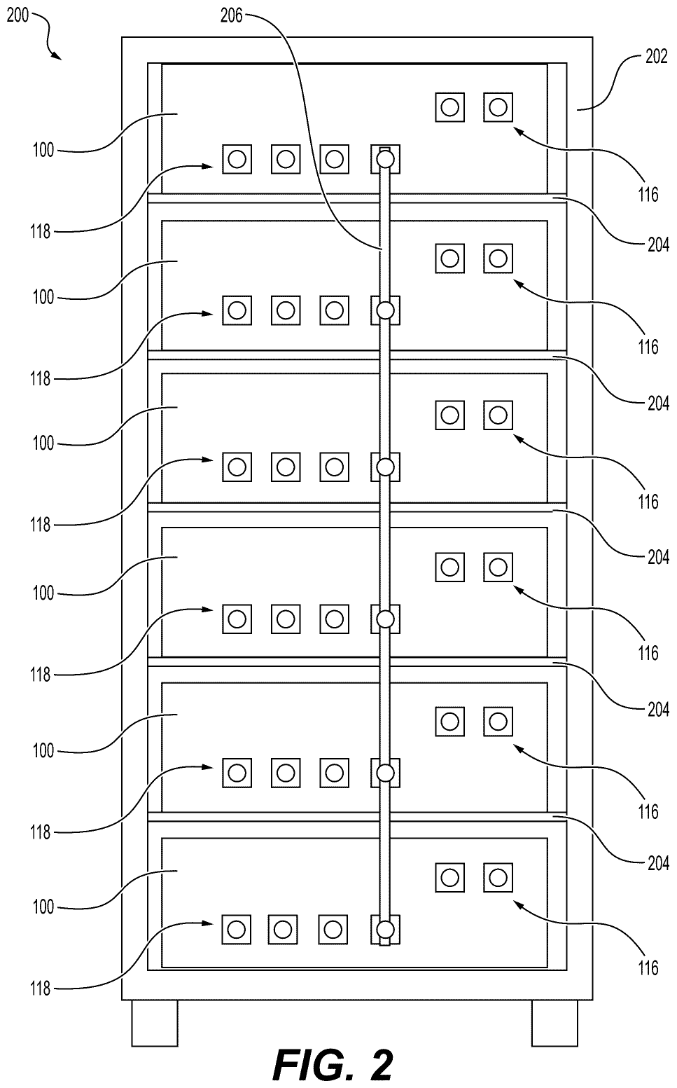

FIG. 2 a plurality of power converters 100 connected together in a power supply unit 200. In one or more embodiments, the power supply unit 200 includes a rack cabinet 202 having a plurality of shelves 204. Each power converter 100 is supported on a respective shelf 204. Because of the arrangement of the first set of electrical connectors 116 and the second set of electrical connectors 118, the power converters 100 can be easily connected using a bus bar 206. While only one bus bar 206 is shown connecting a first connector 118a of the second set of electrical connectors 118 for the purpose of illustration, multiple bus bars 206 can be used to connect some or all of the respective connectors of the sets of electrical connectors 116, 118 as needed according to the particular application. Advantageously, bus bars 206 provide the shortest connection distance between the power converters 100 and consistent conductivity across the bus bars 206. In one or more embodiments, each power converter 100 can provide up to 1 MW, such as 0.1 MW to 1 MW of power and in particular 0.1 MW to 0.5 MW of power, and in one or more embodiments, up to six power converters 100 can be connected in series to deliver up to 3 MW, in particular up to 6 MW, of power.

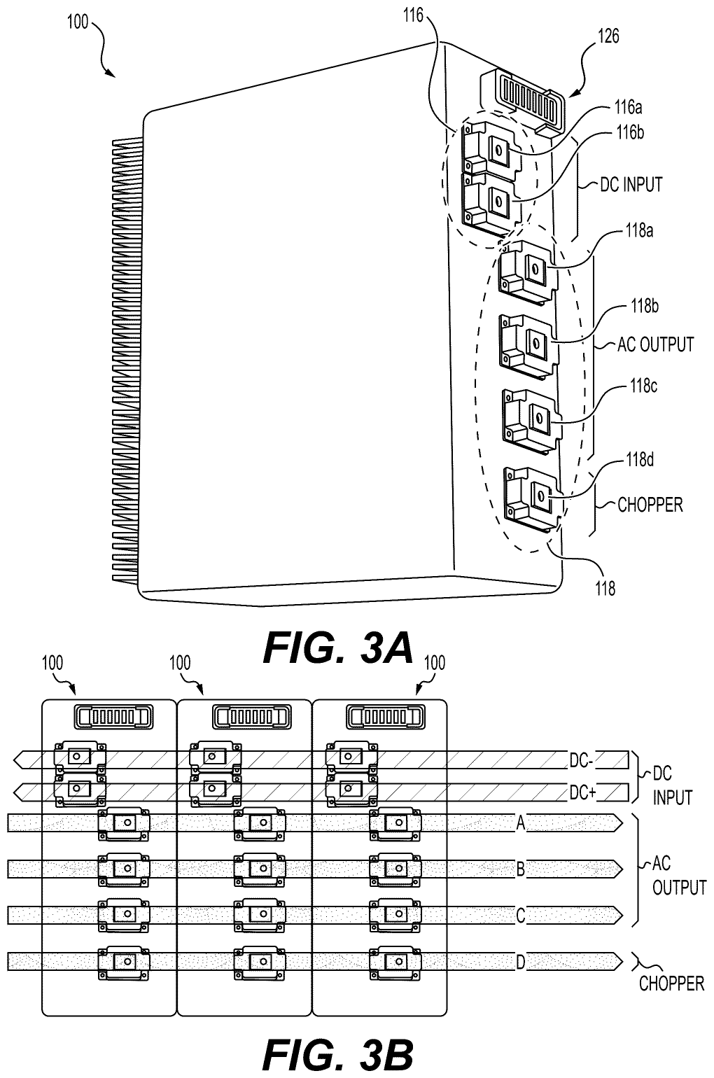

The power converter 100 can be configured to provide a variety of different power outputs depending on how the electrical connections 116, 118 are connected and controlled. FIGS. 3A-3B to 7A-7B depict various connection topologies for converting power using one or more power converters 100 according to the present disclosure.

FIGS. 3A and 3B depict a power converter 100 topology configured as a three-phase inverter, optionally with a chopper. As can be seen in FIGS. 3A and 3B, the first set of electrical connectors 116 act as an input for the power converter 100, and the second set of electrical connectors 118 act as an output for the power converter 100. The first connector 116a of the first set of electrical connectors 116 is connected to a DC− input, and the second connector 116b of the first set of electrical connectors 116 is connected to a DC+ input. The first connector 118a of the second set of electrical connectors 118 provides one phase of the three-phase AC power outputs (i.e., an A-phase). The second connector 118b of the second set of electrical connectors 118 provides a second phase of the three-phase AC power outputs (i.e., a B-phase), and the third connector 118c of the second set of electrical connectors 118 provides the third phase of the three-phase AC power outputs (i.e., a C-phase). In one or more embodiments utilizing the chopper, the fourth connector 118d of the second set of electrical connectors 118 provides a chopper output to dissipate energy, e.g., during motor braking using brake resistors. Such a configuration can be used for rolling stock traction converters, propulsion converters, wind and solar energy inverters, and locomotive auxiliary power (head end power), amongst other possibilities.

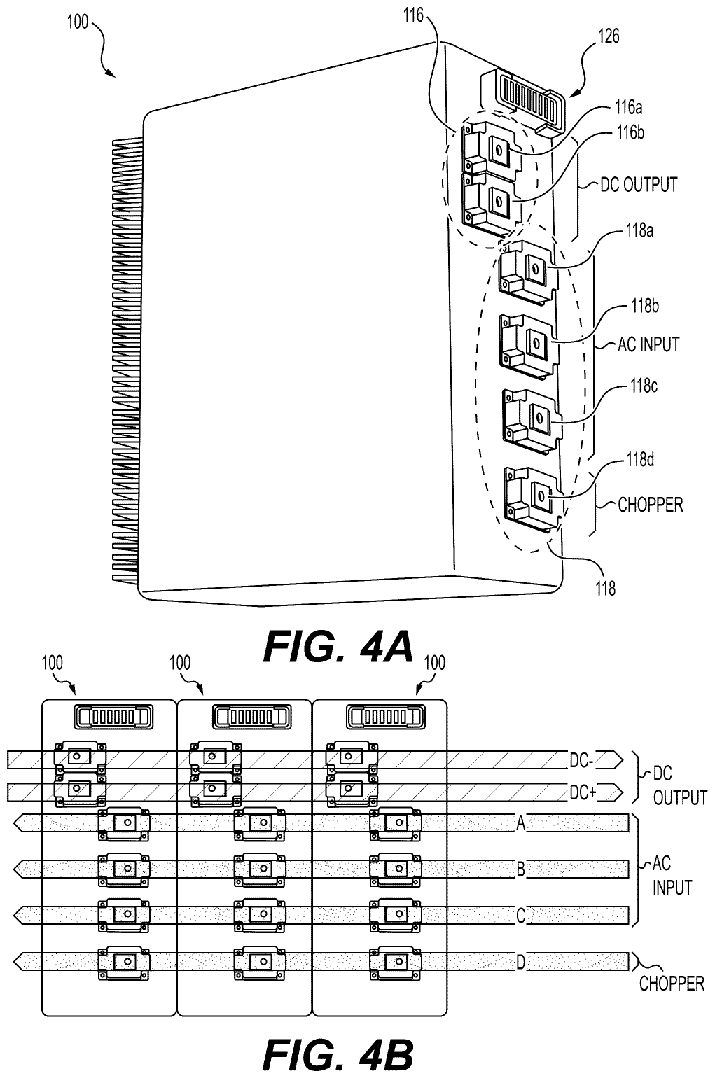

FIGS. 4A and 4B depict a power converter 100 topology configured as a three-phase rectifier, optionally with a chopper. In essence, FIGS. 4A and 4B depict the opposite of FIGS. 3A and 3B, demonstrating the bi-directional nature of the power converter 100 in which the first set of electrical connectors 116 act as an output of the power converter 100 and in which the second set of electrical connectors 118 act as an input of the power converter 100. As shown in FIGS. 4A and 4B, the first connector 118a of the second set of electrical connectors 118 is an input of a first phase of three-phase AC power (i.e., an A-phase). The second connector 118b of the second set of electrical connectors 118 is an input of a second phase of three-phase AC power (i.e., a B-phase). The third connector 118c of the second set of electrical connectors 118 is an input of a third phase of three-phase AC power (i.e., a C-phase). In one or more embodiments where provided, the fourth connector 118d of the second set of electrical connectors 118 is a chopper input, e.g., to regenerate energy during motor braking. Such a configuration can be used for line converters for locomotives and wind energy generators, amongst other possibilities.

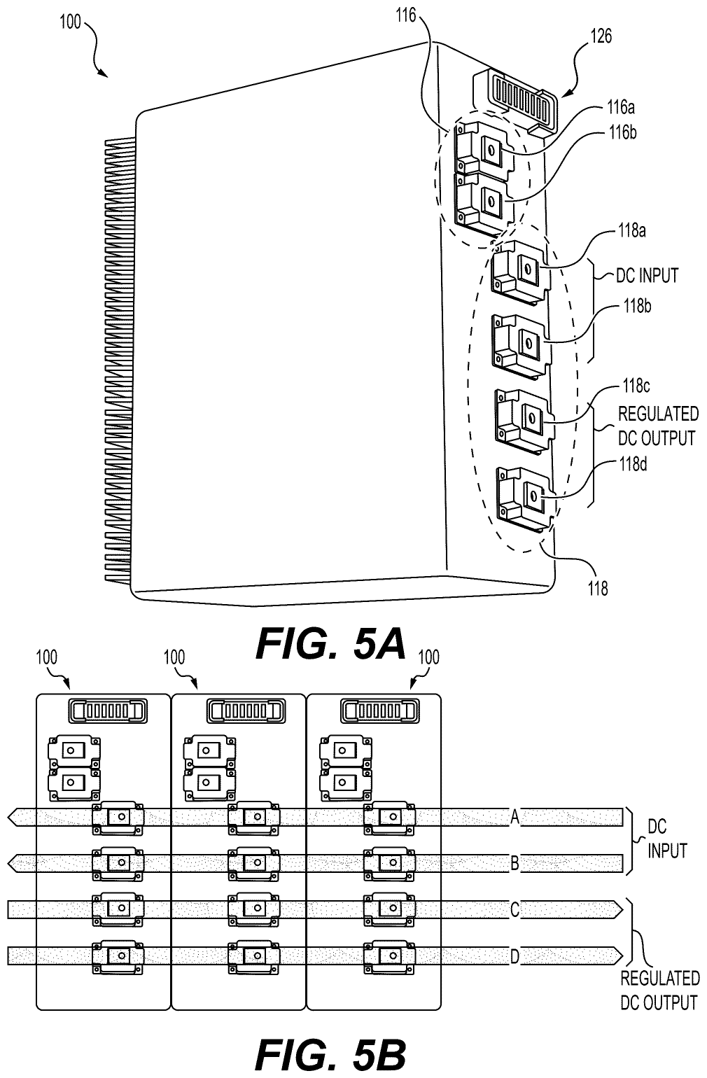

FIGS. 5A and 5B depict a power converter 100 topology configured as a bi-directional DC filter. In one or more such embodiments, the first set of electrical connectors 116 is not used, and the second set of electrical connectors 118 are used as inputs and outputs. For example, as shown in FIG. 5, the first connector 118a is a first DC input (e.g., DC+), and the second connector 118b is a second DC input (e.g., DC−). The third connector 118c is a first regulated DC output (e.g., DC+), and the fourth connector 118d is a second regulated DC output (e.g., DC−). Such a configuration can be used for electromagnetic interference attenuation for wayside power and for intermediate power supplies, amongst other possibilities.

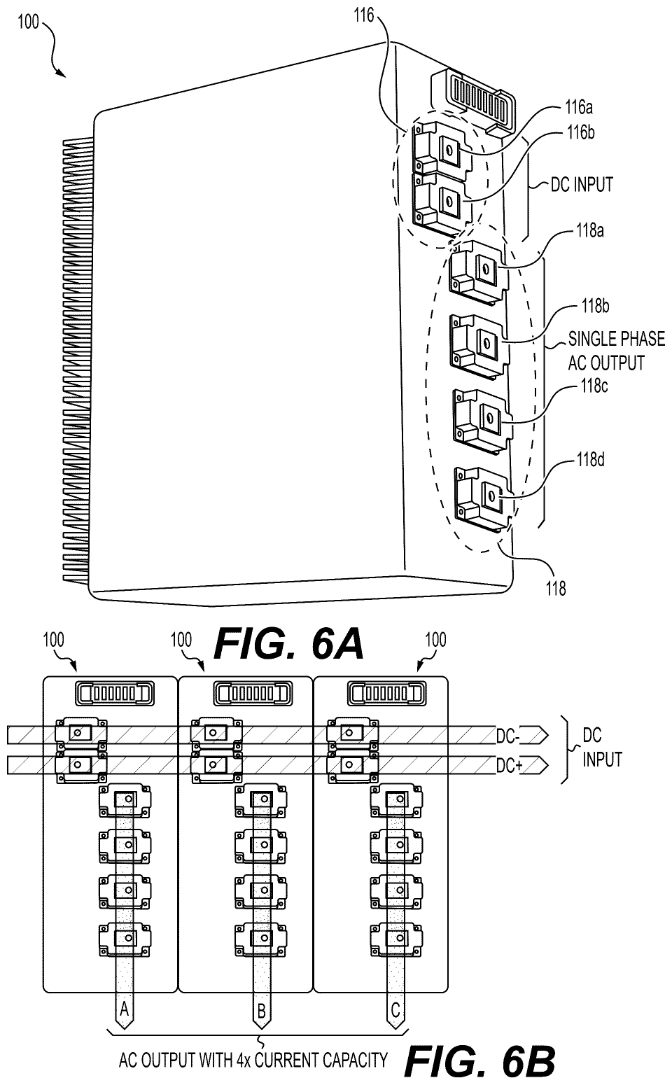

FIGS. 6A and 6B depict a power converter 100 topology configured for outputting a single phase of AC power at up to 4X the current rating. In one or more such embodiments, the first set of electrical connectors 116 are used for a DC input, and two or more of the second set of electrical connectors 118 are connected in series (e.g., by a bus bar) to provide a single phase of AC output at a higher current than the input. As shown in FIG. 6, the first connector 116a of the first set of electrical connectors 116 is a first DC input (e.g., DC+), and the second connector 116b of the first set of electrical connectors 116 is a second DC input (e.g., DC−). In the embodiment depicted, the first connector 118a, the second connector 118b, the third connector 118c, and the fourth connector 118d of the second set of connectors 118 are electrically connected in series to provide one phase of AC power at 4X the current than the output of a single connector of the second set of electrical connectors 118. However, in other embodiments, less than all of the second set of electrical connectors 118 can be connected in series to provide, e.g., 2X or 3X the current output.

As shown in FIG. 6B, three power converters 100 may be provided in parallel to provide three-phase AC power, each at 4X the current. When parallelized in this manner, the respective DC inputs (DC+ and DC−) can be connected together using bus bars (206), e.g., within a server cabinet 202 as shown in FIG. 2. Such a power converter 100 configuration can be used for very high-power locomotives and kiloamp-rated converters, amongst other possibilities.

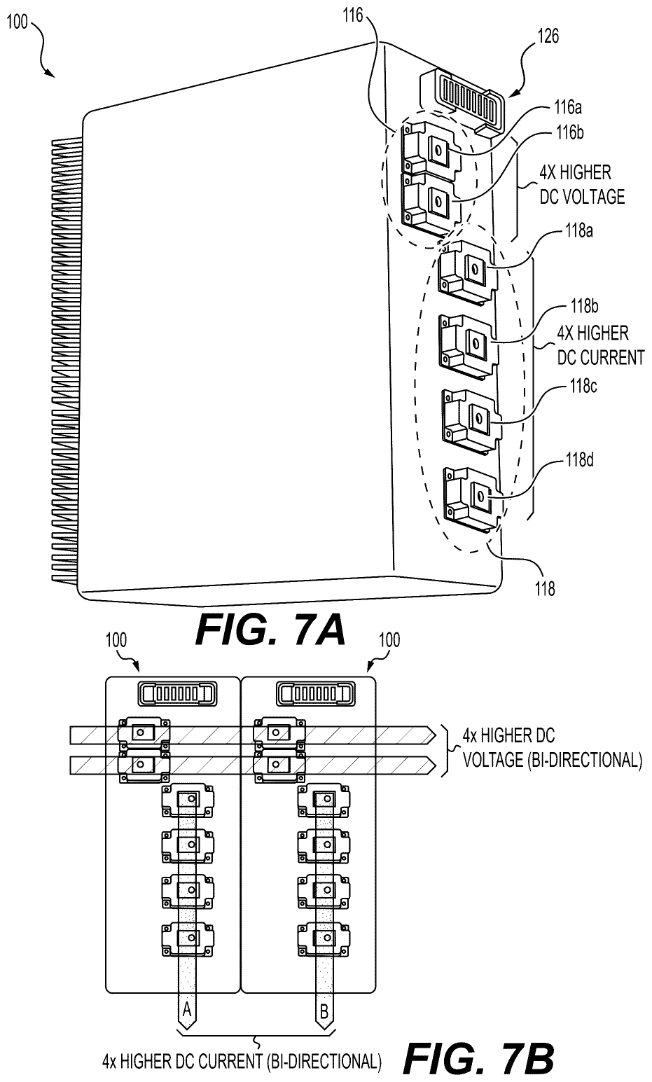

FIGS. 7A and 7B depicts a power converter 100 topology configured for outputting DC power at up to 4X the current rating. In one or more such embodiments, the first set of electrical connectors 116 are used for a DC input, and two or more of the second set of electrical connectors 118 are connected in series (e.g., by a bus bar) to provide a DC output at a higher current than the input. As shown in FIG. 7, the first connector 116a of the first set of electrical connectors 116 is connected to a first DC input (e.g., DC+), and the second connector 116b of the first set of electrical connectors 116 is connected to a second DC input (e.g., DC−). In the embodiment depicted, the first connector 118a, the second connector 118b, the third connector 118c, and the fourth connector 118d of the second set of electrical connectors 118 are connected in series to provide one output of DC power at 4X the current than the output of a single connector of the second set of electrical connectors 118. However, in other embodiments, less than all of the second set of connectors 118 can be connected in series to provide, e.g., 2X or 3X the current output.

As shown in FIGS. 7A and 7B, two power converters 100 may be provided in parallel to provide both DC outputs with each output at 4X the current. When parallelized in this manner, the respective DC inputs (DC+ and DC−) can be connected together using bus bars (206), e.g., within a server cabinet 202 as shown in FIG. 2. Such a power converter 100 configuration can be used for wayside power supplies, amongst other possibilities.

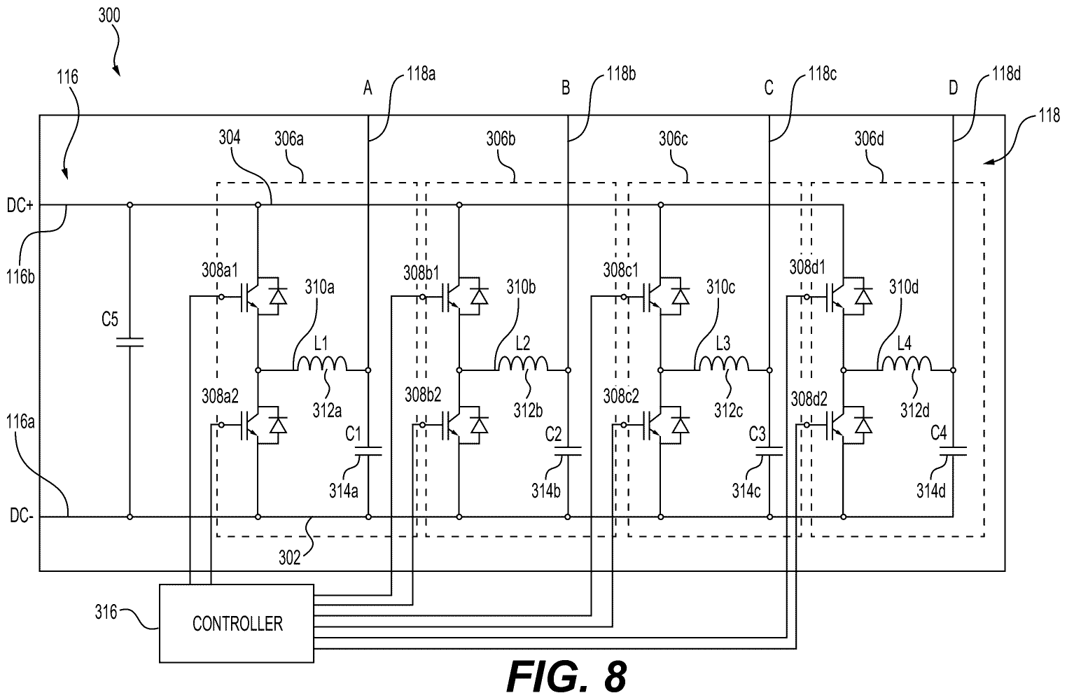

FIG. 8 depicts a switching schematic 300 for controlling the inputs and outputs through the first set of electrical connectors 116 and the second set of electrical connectors 118 of the power converter 100. As can be seen, the schematic 300 includes the first set of electrical connectors 116, which are labeled as DC− at the first connector 116a and DC+ at the second connector 116b that provide a DC bus voltage input or output. For the second set of electrical connectors 118, the first connector 118a, the second connector 118b, the third connector 118c, and the fourth connector 118d are labeled as A, B, C, and D, respectively. Each connector of the second set of electrical connectors 118 is connected to a first bus 302 of the DC bus with the first connector 116a of the first set of connectors 116. The second connector 116b of the first set of connectors 116 is connected to a second bus 304 of the DC bus.

Disposed between the first bus 302 and the second bus 304 are inverter circuits 306a, 306b, 306c, 306d for each of the four connectors 118a, 118b, 118c, 118d of the second set of electrical connectors 118. Each inverter circuit 306a-d includes a first transistor 308a and a second transistor 308b. The emitter of the first transistor 308a₁ is connected to the collector of the second transistor 308a₂. An output 310a of the first inverter circuit 306a is connected to the first connector 118a of the first set of connectors 118. In one or more embodiments, an inductor 312a is disposed on the output 310a. However, in one or more other embodiments, the output 310a to the first connector 118a may have sufficient length and cross-sectional area to provide the desired level of inductance without a separate inductor 312a. Additionally, in one or more embodiments, the inverter circuit 306a includes a capacitor 314a. In such embodiments, the capacitor 314a acts as a filter to smooth the input or output through the first connector 118a.

Each transistor 308a₁, 308a₂-308d₁, 308d₂ is controlled by a controller 316. In particular, the controller 316 operates the transistors 308a₁, 308a₂-308d₁, 308d₂ as switches, allowing current flow across two or more of the transistors 308a₁, 308a₂-308d₁, 308d₂ while blocking current flow across others of the transistors 308a₁, 308a₂-308d₁, 308d₂. Depending on the particular power input to which particular set of electrical connectors 116, 118, the controller 316 is configured to operate the power converter according to any of the various topologies described above in relation to FIGS. 3A-3B to 7A-7B. For example, the controller 316 may include a memory having program instructions stored thereon to cause the transistors 308a₁, 308a₂-308d₁, 308d₂ to allow or block current flow through the power converter 100 to provide AC-to-DC, DC-to-AC, AC-to-AC, or DC-to-DC conversions.

In one or more embodiments, the controller 316 drives the DC signal to produce an AC signal using pulse width modulation. In particular, the transistors 308a₁, 308a₂-308d₁, 308d₂ are switched such that the pulses increase in duration until reaching a maximum pulse and are then decreased in duration until the signal is inverted. In this way, the average voltage of the signal increases until reaching a peak and then decreases in a generally sinusoidal manner, mimicking an AC signal.

The controller 316 described herein may be embodied in any of a variety of general-purpose processors, digital signal processors (DSPs), application-specific integrated circuits (ASIC), Field Programmable Gate Array (FPGA) or other Programmable Logic Device (PLD), individual gate or transistor logic, individual hardware components, or any combination thereof. A general-purpose processor may be a microprocessor, but in the alternative, the processor may be any commercially available processor, microcontroller, or state machine. A processor may also be implemented as a combination of computing devices, such as a combination of a DSP and a microprocessor, a plurality of microprocessors, one or more microprocessors in combination with a DSP core, or any other such configuration.

In one or more embodiments, the transistors 308a₁, 308a₂-308d₁, 308d₂ are silicon (Si) insulated-gate bipolar transistors (IGBT). In one or more embodiments, the transistors 308a₁, 308a₂-308d₁, 308d₂ are silicon carbide (SiC)-based transistors, such as SiC field-effect transistors (FET). In embodiments where used, the SiC FET provides faster switching, allowing for more refined pulse width modulation control for the various power conversions performed by the power converter 100. An example of a suitable SiC MOSFET is the CoolSiC™ fourpack module (available from Infineon Technologies AG, Munich, Germany). It is expected that other transistor technologies, such as GaN and similar technologies, will also be suitable for use in embodiments of the present disclosure.

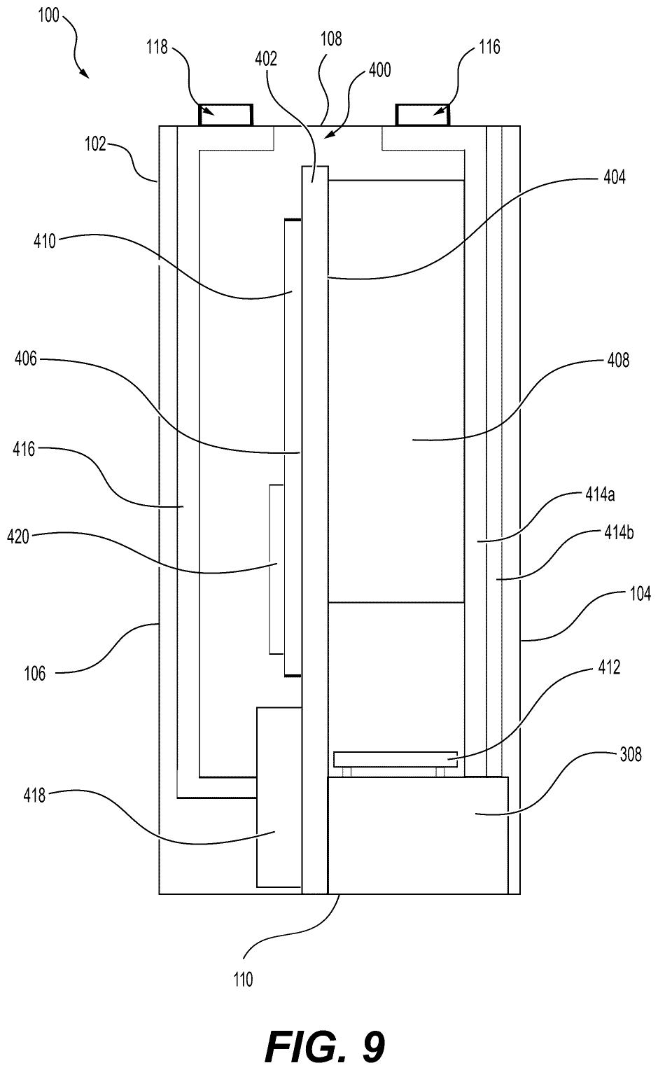

FIG. 9 schematically depicts a layout of the internal components of the power converter 100 according to embodiments of the present disclosure. As can be seen, the housing 102 of the power converter 100 defines an interior 400. In the housing 102, a panel 402 substantially divides the interior 400. The panel 402 has a first side 404 and a second side 406 that provide a mounting structure for various electronic components. In one or more embodiments, a capacitor bank 408 is disposed on the first side 404 of the panel 402. On the second side 406, a motherboard 410 is mounted to the panel 402, which provides the processor, memory, and communication capabilities for the various electronic components within the power converter 100. The motherboard 410 may incorporate or have mounted thereon the controller 316 for controlling the switching described in relation to FIG. 8.

Further, as shown in FIG. 9, the panel 402 also has the transistors 308 disposed on the first side 404. In one or more embodiments, the transistors 308 have a control board 412, which may control the switching of the transistors 308 in conjunction with the motherboard 410 or in the alternative to the motherboard 410. That is, the function of the controller 316 as shown in FIG. 8 may be fulfilled by either or both of the motherboard 410 and the control board 412. In one or more embodiments, a communication link is provided between the motherboard 410 and the control board 412, e.g., using a wired connection. As can be seen in FIG. 9, the transistors 308 are in electrical communication with DC bus bars 414a, 414b, which connects the first set of electrical connectors 116 to the transistors 308 for DC outputs/inputs. That is, each connector (e.g., DC+ and DC−) has a respective bar 414a, 414b. Additionally, a conductor bar 416 is in electrical communication with the transistors 308, which connects the transistors to the second set of connectors 118 for AC or DC inputs/outputs. While one conductor bar 416 is shown, each connector of the second set of connectors 118 would have a respective conductor bar 416.

In one or more embodiments, the conductor bars 416 extend from the transistors 308 through the panel 402 to the second side 406, and arranged on or through the panel 402 are current sensors 418 that monitor the input/output current of the transistors 308. In one or more embodiments, including the embodiment shown in FIG. 9, the panel 402 has mounted thereon one or more drivers 420 for various sensors, including, e.g., the current sensors 418, temperature sensors, vibration sensors, moisture sensors, etc., within the housing 102.

The capacitor bank 408 is provided internal to the power converter 100 to stabilize the switching of the transistors 308. In one or more embodiments, the capacitor bank 408 is connected between the DC bus bars 414a, 414b as a DC link capacitor for the inverter circuits. In one or more embodiments, the transistors are switched by the controller at a frequency of up to 50 kHz, e.g. in a range from 5 kHz to 50 kHz, in particular in a range from 10 kHz to 30 kHz. Conventionally, transistors in current power converters are switched at frequencies ten times or lower (˜2 kHz) than the transistors 308 of the presently disclosed power converter 100.

Further, as compared to conventional power converters, the presently disclosed power converter 100 includes its own logic controllers and sensors as discussed above. In this way, each power converter can monitor its own status, allowing for recognition of faults more quickly and efficiently. Additionally, each power converter 100 can operate independently such that power converters 100 that reach end-of-life or that are damaged can be swapped out individually. Notwithstanding, the power converters 100 are programmed to operate collectively (including with a system-level master controller), recognizing one another when connected in the same system and operating together to provide a desired power output. In this way, the power converters 100 can be used in scalable systems to provide application-specific levels of power output. Conventional power converters did not include logical control and monitoring at the individual module level, which was instead provided at the system level. As such, it was difficult to detect issues with individual modules early, often causing unnecessary system level failure. Further, the modules were not scalable to different application levels.

The physical layout of the internal components of the power converter 100 is designed to account for typical environmental stresses associated with transportation, installation, and use of the power converter 100. That is, the power converter 100 is designed to handle the shocks and vibrations associated with transportation, installation, and use without degrading the quality of the power conversion capabilities of the power converter 100. Additionally, the physical layout of the power converter 100 allows for accurate thermal management of the components within. Forced air or liquid cooling can be employed to avoid excessive temperature while providing operation at maximum performance for long periods of time. By accurately managing the thermal load on the power converter 100, the time that the power converter 100 can operate at maximum performance increases, increasing the rating of the system in which the power converter 100 is deployed. By contrast, a system that becomes overheated cannot operate to its maximum performance because, e.g., switching speeds must be decreased to prevent heat generation.

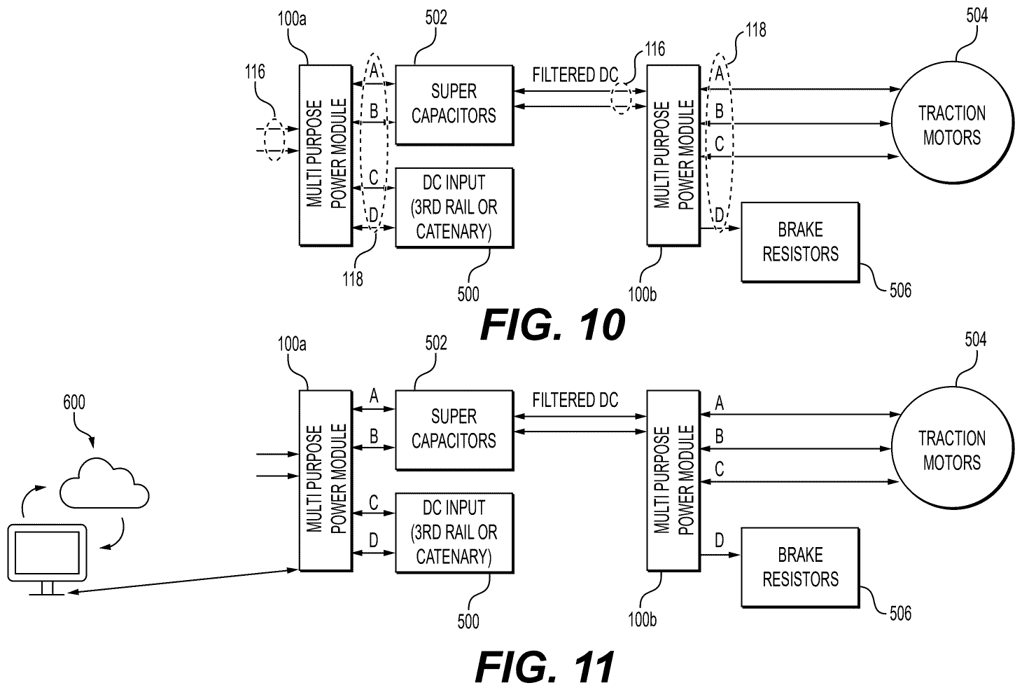

FIG. 10 depicts an example embodiment in which the power converter 100 can be deployed to control traction motors. As shown in FIG. 10, a first power converter 100a is operating as a bi-directional DC filter (e.g., as shown in FIGS. 5A-5B) and receives a first DC input through the second set of electrical connectors 118 from a DC power source 500, such as rectified DC power from a diesel generator, a third rail, catenary, or battery, for example. The first power converter 100a outputs through the second set of electrical connectors 118 a regulated DC power. For example, DC power may be supplied at a level of 400 V, and the power converter may step the voltage up to 1200 V. In one or more embodiments, the regulated DC power output by the power converter is filtered through a bank of supercapacitors 502. As discussed above in relation to FIG. 5, the first set of connectors 116 is not used in the bi-directional DC filter operation mode.

The filtered DC power is then provided as an input on the first set of connectors 116 of a second power converter 100b. The second power converter 100b is operating as a three-phase inverter with chopper as discussed above in relation to FIGS. 3A-3B. In a particular example, the second set of electrical connectors 118 provides a three-phase AC power output to control a traction motor 504 of a train. Further, through the second set of connectors 118, a chopper output is provided to brake resistors 506. While one second power converter 100b is shown with one traction motor 504, a train may include four to six traction motors 504 per locomotive, and each traction motor 504 will have a respective power converter 100b.

The embodiment shown in FIG. 10 is merely exemplary, and the power converter can be used in a variety of other systems, such as in systems including wind turbines, solar panels, electric vehicle charging, energy storage, and mining, amongst other possibilities.

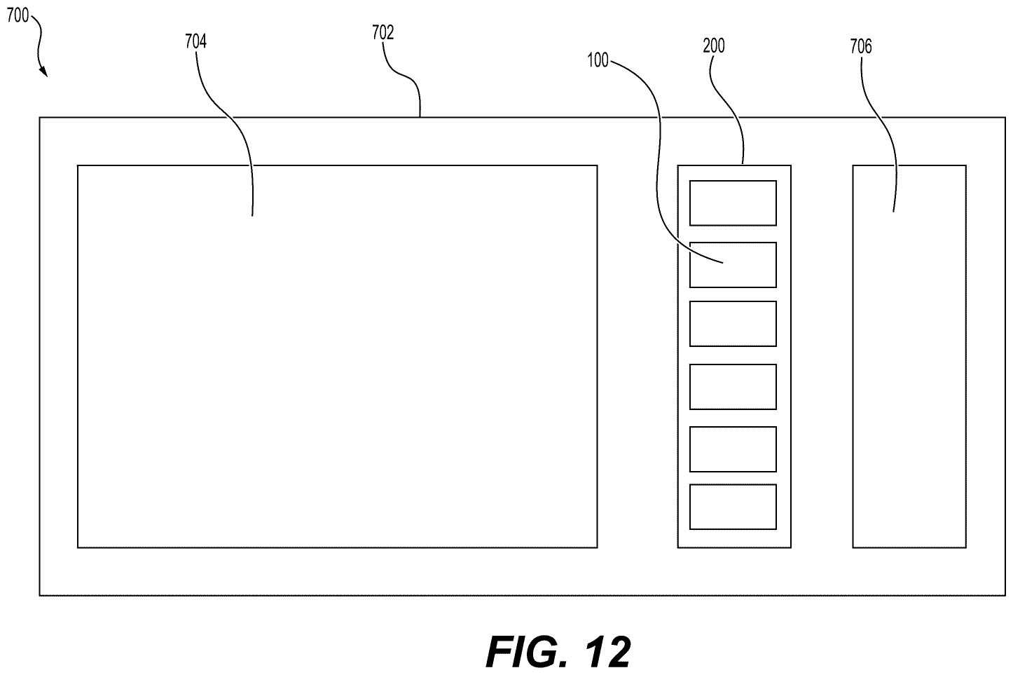

FIG. 11 depicts the system of FIG. 10 with advanced edge computing technology 600 to provide condition monitoring. As mentioned above, the individual power converters 100 each include controllers for operating and monitoring. In this way, embodiments of the disclosed power converter 100 can provide real-time monitoring and analysis of peripheral components, such as motors, gearboxes, power cables, and power inputs, amongst other possibilities, and report the status of the system to a central instance (e.g., server). In this way, assets within the system can be monitored and serviced as necessary based on information collected by the power converter.

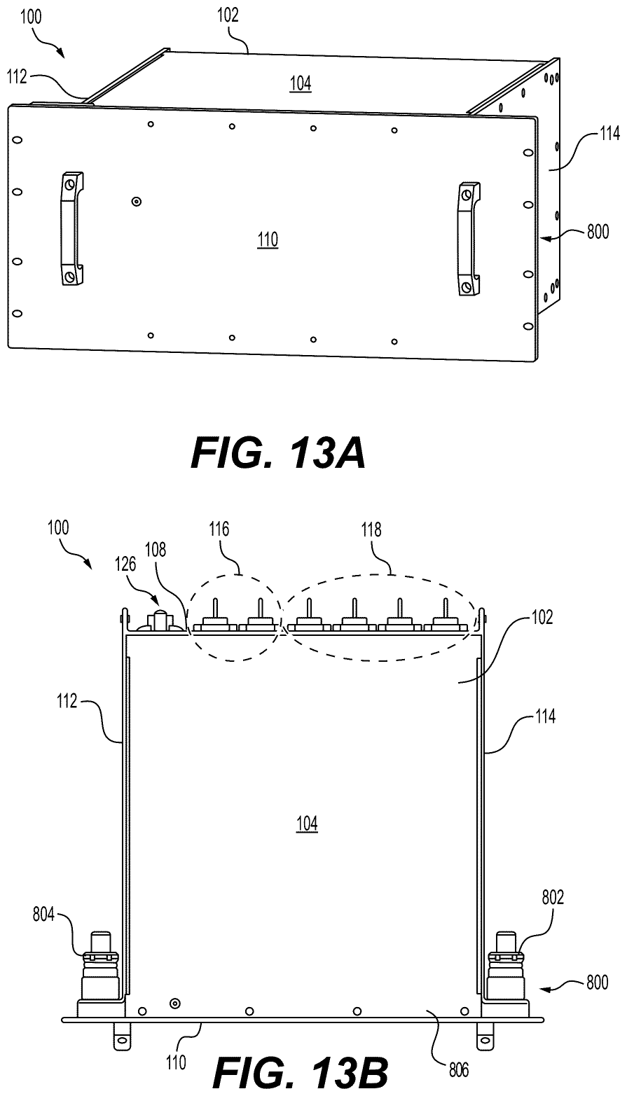

FIG. 12 depicts another system in which the power converter 100 as disclosed herein may be used. In particular, the power converter 100 is incorporated into a power storage container 700. The power storage container 700 is, for example, a standard size shipping container 702 that can be transported on a train, cargo ship, or semi tractor trailer (e.g., an intermodal shipping container as defined according to ISO 668:2020). Disposed within the container 700 is an energy storage device 704, such as a battery bank or hydrogen electrolyzers, amongst other possibilities. The energy storage device 704 provides DC power to the power converter 100 or power supply unit 200 as disclosed herein, which can be stepped up or down or converted to AC power as needed for a particular application. In one or more embodiments, the power storge container 700 may output power at grid frequency (50 Hz or 60 Hz), and the power storage container 700 may further include a filtering module 706 external to the power converter 100. Advantageously, because the power converter 100 includes an internal capacitor bank and conductor bars with a desired level of inductance that together provide some filtering, the size of the external filtering module 706 can be reduced compared to conventional systems. In one or more embodiments, the filtering module 706 can be used to provide a stable grid frequency by, e.g., eliminating unacceptable levels of harmonics. A power storage container 700 incorporating one or more of the multi-purpose power converter 100 as described herein can provide a standardized package for multiple different applications, can be mass produced, and can provide drop-and-go power to support renewable energy grids, outages, and electric/hybrid vehicles (e.g., trains and boats).

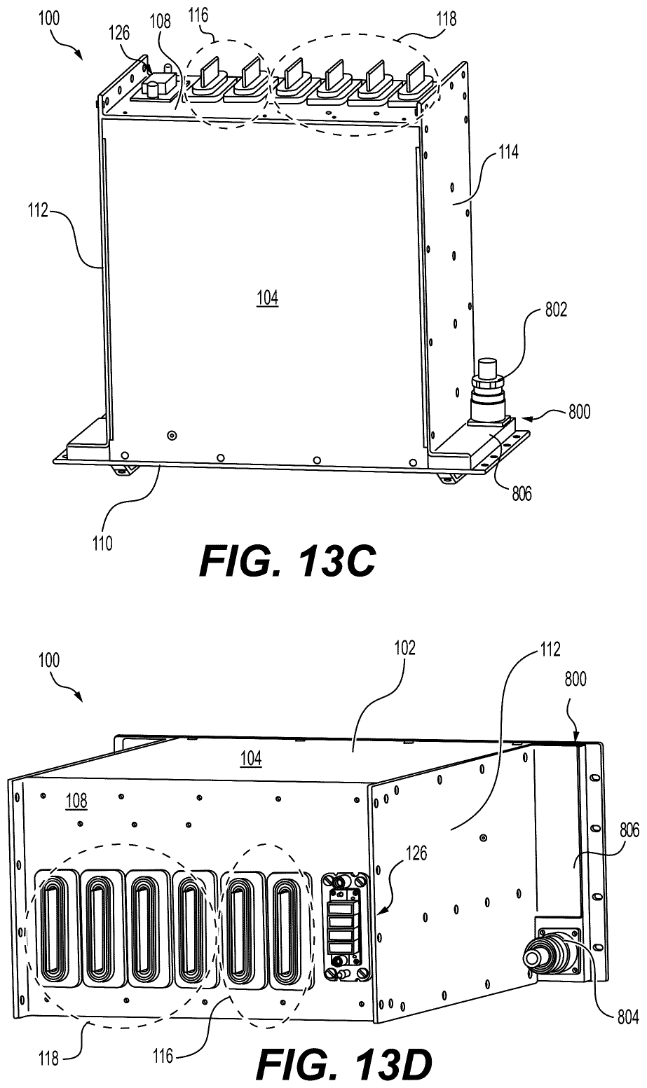

FIGS. 13A-13D depict an embodiment of a power converter 100 in which the power converter 100 is liquid cooled. As can be seen, the structure of the power converter 100 is largely the same as depicted, e.g., in FIG. 1 in that the power converter 100 includes a housing 102 having a first side surface 102, a second side surface 104, a first peripheral surface 108, a second peripheral surface 110, a third peripheral surface 112, and a fourth peripheral surface 114. Further, the power converter 100 includes a first set of connectors 116 and a second set of connectors 118 disposed on the first peripheral surface 108. In the embodiment shown in FIGS. 13A-13D, the first set of connectors 116 and the second set of connectors 118 are disposed in a single continuous line. Further, in embodiment shown in FIGS. 13A-13D, the first set of connectors 116 and the second set of connectors 118 are blade connectors.

In contrast to the power converter 100 of FIG. 1 that includes heatsink fins 124 on the second peripheral surface 110, the power converter 100 of FIGS. 13A-13D is liquid cooled. As can be seen, a liquid cooling system 800 is attached to the second peripheral surface 110. In one or more embodiments, the liquid cooling system 800 includes a first liquid port 802 and a second liquid port 804. The first and second liquid ports 802, 804 provide inlet and outlet flow of liquid to the liquid cooling system 800. Disposed between the first liquid port 802 and the second liquid port 804 is a cooling chamber 806. In one or more embodiments, the liquid flows into one of the first liquid port 802 or the second liquid port 804, through the cooling chamber 806, and out of the other of the first liquid port 802 or the second liquid port 804. In one or more embodiments, the cooling chamber 806 may include a serpentine channel, for example, that winds back and forth across the second peripheral surface 110 between the first liquid port 802 and the second liquid port 804. In this way, the liquid flowing through the liquid cooling system 800 will absorb heat generated by the transistors mounted against the second peripheral surface 110 and transport the heat away from the power converter 100. A variety of liquids are suitable for use in the liquid cooling system 800, such as water, glycol, water/glycol mixtures, and dielectric fluids, amongst other possibilities.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A bi-directional power converter, comprising:
a housing comprising a first side surface, a second side surface, and a plurality of peripheral surfaces, the second side surface being opposite to and spatially disposed from the first side surface and the plurality of peripheral surfaces connecting the first side surface to the second side surface around a periphery of the housing;
a first set of electrical connectors disposed on a first peripheral surface of the plurality of peripheral surfaces; and
a second set of electrical connectors disposed on the first peripheral surface;
wherein the first set of electrical connectors are arranged in a first line;
wherein the second set of electrical connectors are arranged in a second line;
wherein the first line and the second line are each substantially parallel to an edge of the housing formed by an intersection of the first side surface and the first peripheral surface; and
wherein the first set of connectors are configured to transmit or receive electrical energy at at least one of a first current, a first voltage, or a first current form and the second set of connectors are configured to receive or transmit electrical energy at at least one of a second current, a second voltage, or a second current form that is different from the at least one of the first current, the first voltage, or the first current form.

2. The bi-directional power converter of claim 1, wherein the first line and the second line are offset from each other between the first side surface and the second side surface.

3. The bi-directional power converter of claim 1, wherein the first line and the second line define a single continuous line.

4. The bi-directional power converter according to claim 1, wherein the first set of electrical connectors and the second set of electrical connectors are screw connectors or blade connectors.

5. The bi-directional power converter according to claim 1, wherein the first set of connectors comprises a first connector and a second connector, the first connector connected to a first bus and the second connector connected to a second bus, wherein the bi-directional power converter further comprises a plurality of inverter circuits connected between the first bus and the second bus, and wherein each connector of the second set of connectors is connected to the second bus such that an inverter circuit of the plurality of inverter circuits and a connector of the second set of connectors is alternatingly connected to the second bus.

6. The bi-directional power converter according to claim 1, wherein a thickness of the bi-directional power converter defined as a distance between the first side surface and the second side surface is in a range from 100 mm to 500 mm.

7. The bi-directional power converter according to claim 6, wherein the first side surface and the second side surface each comprise a length and a width, the length and the width each being perpendicular to the thickness and the length being measured parallel to an edge defined by an intersection between the first side surface and the first peripheral surface, and wherein the length is 1000 mm or less and the width is 1100 mm or less.

8. The bi-directional power converter according to claim 1, wherein the plurality of peripheral surfaces comprises a second peripheral surface opposite to the first peripheral surface and wherein the second peripheral surface comprises a heat dissipation feature.

9. The bi-directional power converter according to claim 1, further comprising a liquid cooling system disposed on the second peripheral surface, wherein the liquid cooling system comprises a liquid inlet and a liquid outlet configured to provide liquid flow through the liquid cooling system.

10. A power supply unit, comprising a plurality of the bi-directional power converters according to claim 1.

11. The power supply unit of claim 10, wherein the plurality of bi-directional power converters are contained in a rack cabinet.

12. A bi-directional power converter, comprising:
a first set of electrical connectors configured to receive or transmit electrical energy at at least one of a first current, a first voltage, or a first current form;
a second set of electrical connectors configured to receive or transmit electrical energy at at least one of a second current, a second voltage, or a second current form;
a controller;
a plurality of SiC-based transistors in electrical communication with the first set of electrical connectors and with the second set of electrical connectors;
wherein the controller is configured for switching, using pulse width modulation, the plurality of SiC-based transistors to change the at least one of the first current, the first voltage, or the first current form to the at least one of the second current, the second voltage, or the second current form; and
wherein the switching is at a frequency up to 50 KHz.

13. The bi-directional power converter of claim 12, wherein the first set of connectors comprises a first connector and a second connector, the first connector connected to a first bus and the second connector connected to a second bus, wherein the SiC-based transistor define a plurality of inverter circuits connected between the first bus and the second bus, and wherein each connector of the second set of connectors is connected to the second bus such that an inverter circuit of the plurality of inverter circuits and a connector of the second set of connectors is alternatingly connected to the second bus.

14. The bi-directional power converter of claim 13, further comprising a capacitor bank connected between the first bus and the second bus such that the capacitor bank is electrically disposed between the first set of connectors and a first inverter circuit of the plurality of inverter circuits.

15. The bi-directional power converter of claim 12, further comprising a plurality of current sensors configured to sense current flowing between each of the plurality of SiC-based transistors and the second set of electrical connectors, wherein the controller monitors a status of the bi-directional power converter based at least in part on feedback from the plurality of current sensors.

16. The bi-directional power converter of claim 12, wherein the controller is configured to operate independently to control the bi-directional power converter without another controller external to the bi-directional power converter.

17. The bi-directional power converter of claim 12, wherein the controller is configured to communicate and coordinate power conversion operations with one or more other controllers of one or more other bi-directional power converters.

18. The bi-directional power converter of claim 12, wherein the first set of electrical connectors and the second set of electrical connectors are configurable between a plurality of topologies for changing the at least one of the first current, the first voltage, or the first current form to the at least one of the second current, the second voltage, or the second current form.

19. A power supply unit comprising a plurality of the bi-directional power converters according to claim 12.

20. The power supply unit of claim 19, wherein the first set of electrical connectors of each bi-directional power converter comprises a first connector and a second connector, wherein the first connector of the first set of electrical connectors of each of the plurality of bi-directional power converters is electrically connected and the second connector of the first set of electrical connectors of each of the plurality of bi-directional power converters is electrically connected, and wherein the first connectors and the second connectors are configured for DC power input/output.

21. The power supply unit of claim 20, wherein the second set of electrical connectors of each bi-directional power converter comprises a first connector, a second connector, and a third connector;
wherein the first connector of the second set of electrical connectors of each of the plurality of bi-directional power converters is electrically connected, the second connector of the second set of electrical connectors of each of the plurality of bi-directional power converters is electrically connected, and the third connector of the second set of electrical connectors of each of the plurality of the bi-directional power converters is electrically connected; and
wherein the first connectors, the second connectors, and the third connectors are configured for 3-phase AC power input/output.

22. The power supply unit of claim 20, wherein the second set of electrical connectors of each bi-directional power converter comprises a first connector, a second connector, and a third connector;
wherein the plurality of the bi-directional power converters comprises a first bi-directional power converter, a second bi-directional power converter, and a third bi-directional power converter;
wherein the first connector, the second connector, and the third connector of the second set of connectors of the first bi-directional power converter are electrically connected, the first connector, the second connector, and the third connector of the second set of connectors of the second bi-directional power converter are electrically connected, and the first connector, the second connector, and the third connector of the second set of connectors of the third bi-directional power converter are electrically connected; and
wherein the second set of electrical connectors of the first bi-directional power converter is configured to output a first phase of 3-phase AC power, the second set of electrical connectors of the second bi-directional power converter is configured to output a second phase of 3-phase AC power, and the second set of electrical connectors of the third bi-directional power converter is configured to output a third phase of 3-phase AC power.

23. The power supply unit of claim 20, wherein the plurality of the bi-directional power converters comprises a first bi-directional power converter and a second bi-directional power converter;
wherein the second set of electrical connectors of the first bi-directional power converters are electrically connected and the second set of electrical connectors of the second bi-directional power converters are electrically connected; and
wherein the second set of electrical connectors of the first bi-directional power converter and the second set of connectors of the second bi-directional power converter are configured to provide a further DC power input/output at a different voltage or current that the DC power input/output of the first set of electrical connectors.

24. The power supply unit of claim 19, wherein the second set of electrical connectors of each bi-directional power converter comprises a first connector, a second connector, a third connector, and a fourth connector;
wherein each first connector of the plurality of bi-directional power converters is electrically connected, each second connector of the plurality of bi-directional power converters is electrically connected, each third connector of the plurality of bi-directional power converters is electrically connected, and each fourth connector of the plurality of bi-directional power converters is electrically connected; and
wherein the first connectors and the second connectors of the plurality of bi-directional power converters are configured for a first DC power input/output and the third connectors and the fourth connectors of the plurality of bi-directional power converters are configured for a second DC power input/output that is different from the first DC power input/output in at least one of current, voltage, or pulse width or frequency.

25. A power storage container, comprising:
the bi-directional power converter according to claim 12; and
an energy storage device in electrical communication with the bi-directional power converter;
wherein the energy storage device is configured to output electrical power at at least one of a first current, a first voltage, or a first current form to the bi-directional power converter and wherein the bi-directional power converter is configured to output electrical power at at least one of a second current, a second voltage, or a second current form that is different from at least one of the first current, the first voltage, or the first current form.

26. The power storage container of claim 25, wherein the energy storage device comprises a battery bank or a hydrogen electrolyzer.

27. The power storage container according to claim 25, wherein the container is an intermodal shipping container according to ISO 668:2020.

28. A method of operating a bi-directional power converter, comprising:
providing electrical energy at at least one of a first current, a first voltage, or a first current form to a first set of electrical connectors;
switching a plurality of transistors in electrical communication with the first set of electrical connectors to change the at least one of the first current, the first voltage, or the first current form to at least one of a second current, a second voltage, or a second current form;
transmitting the electrical energy at the at least one of the second current, the second voltage, or the second current form to a second set of electrical connectors;
wherein a controller controls the switching of the plurality of transistors using pulse with modulation and at a frequency of up to 50 KHz.

29. The method of claim 28, further comprising sensing current flowing between each of the plurality of transistors and the second set of electrical connectors using a plurality of current sensors; and
monitoring, using the controller, a status of the bi-directional power converter based at least in part on feedback from the plurality of current sensors.

30. The method of claim 28, further comprising connecting the bi-directional power converter to one or more other bi-directional power converters to create a power supply unit.
